(19) United States
(12) Patent Application Publication
(10) Pub. No.: US 2006/0139901 A1
(43) Pub. Date: Jun. 29, 2006

(54) Double-sided electronic module for hybrid smart card

(76) Inventors: Virgile Meireles, Mouans Sartoux (FR); Pierre Benato, Roquefort les Pins (FR)

Correspondence Address: JAMES C. LYDON, 100 DAINGERFIELD ROAD, SUITE 100, ALEXANDRIA, VA, 22314, US

(21) Appl. No.: 11/315,273

(22) Filed: Dec. 23, 2005

(30) Foreign Application Priority Data
Dec. 28, 2004 (FR) 0413951

(51) Int. Cl. H05K 7/08; H05K 7/06; H05K 7/02; H05K 7/10

(52) U.S. Cl. 361/760

(57) ABSTRACT

The invention concerns a double-sided electronic module of a hybrid contact-contactless smart card designed to be lodged in a cavity of the card and to be connected to the bonding pads of the antenna which is embedded in the card, the module including a group of contacts (52) on a first side of the support, some of the contacts each covering a through hole in the support. According to a main characteristic of the invention, on the second side of the module are screen printed first routing traces connected by their first end (55) to the through holes and by the other end to the chip's bonding pads, and second routing traces each connected respectively to a screen printed bonding pad (57 and 59) on one side and to two of the chip's bonding pads on the other side, the bonding pads being positioned so that, when inserting the module in the cavity, they are opposite the antenna's bonding pads and allow the module to be bonded along its whole periphery.

### TECHNICAL FIELD

The invention relates to a double-sided integrated circuit designed for a hybrid contact-contactless smart card and specifically concerns a double-sided electronic module for a hybrid smart card.

### BACKGROUND ART

Contactless smart cards are currently widely used in many fields such as the transport sector and the banking sector as well as for identifying persons and objects. Contactless smart cards feature an antenna embedded in the card connected to an electronic chip inserted in the card which is used for developing, storing and processing the information.

Such cards allow the exchange of information with the outside by remote, and therefore contactless, electromagnetic coupling, between the antenna and a second antenna located in the associated reader. Hybrid contact-contactless smart cards have a group of contacts flush with the card surface so that the exchange of information can be accomplished by electrical transmission of data between the flush contacts of the card's electronic module as well as the contacts of a reader's reading head into which the card is inserted.

The chip of hybrid smart cards must therefore be connected to the group of flush contacts, on the one hand, and to the antenna's bonding pads, on the other hand. Several solutions are used to achieve this double connection of chips in hybrid smart cards.

A first solution illustrated in cross-section in FIG. 1 consists in creating an electronic module made up of an electrically non-conductive support 10 bearing on the first side the group of flush contacts 12 adapted for connecting the contacts of the reader's reading head, and on the other side, contacts 14 adapted for connecting the card's antenna. A chip 16 is then connected both to the group of flush contacts 12 using welded gold wires 18 passing through the support via holes 20 designed for this purpose, and to contacts 14 of the antenna by welded gold wires 22 as well. The chip 16 and the wires 18 and 22 are then protected and sealed by a resin 24 cast on top. When the resin has hardened, the chip and the wires are thus encased and only one part of the contacts 14 designed to be connected to the antenna's bonding pads is apparent as shown in FIG. 2. Such a module is known as a double-sided integrated circuit as it features contacts on both sides unlike a single-sided integrated circuit which is used in manufacturing contact smart cards and comprises only the group of flush contacts.

As shown in FIG. 3, the module thus constituted lodges in a milled cavity in the card body 30. The cavity includes an internal portion 32 with a thickness of 600 μm which receives the encased chip and an external portion 34 with a thickness of 200 μm which receives the part of the circuit featuring the group of flush contacts. Two pits 36 are also milled in the external portion of the cavity and allow the bonding pads to be moved apart from the antenna.

The next step consists in inserting the module using a glue enabling the module to be fixed on the external part of the cavity and a conductive glue enabling the module to be connected to the antenna's bonding pads moved apart thanks to the two pits 36. The small surface of the external cavity 34 due to the size of the chip encased in the resin 24 does not allow the glue to be applied over the entire perimeter. As a result, only two locations 40 and 42, shown shaded in the figure, are covered with glue. For this reason, the connections made with conductive glue between the contacts 14 of the module and the antenna pads located at the bottom of the pits 36 are subjected to maximum mechanical bending stresses when the card is folded along its width in particular. The welding of gold connecting wires 22 between the chip 16 and the antenna contacts 14 are also subjected to mechanical bending stress when the card is folded. The electronic module is thus subjected to stresses that may alter the connection with the antenna and therefore the card's reliability. Furthermore, the cavities milled in the card body weaken the card, considering its small thickness of 0.76 mm which is required by the standard. The location of contacts 14 placed very close to the module edges because of the large size of the encased chip also represents a problem when installing the module in the cavity, since conductive glue may move back up and create short-circuits with the flush contacts.

In addition to these technical problems of mechanical strength and reliability, the production cost of such modules must also be taken into account. Double-sided circuits are about three times as expensive as single-sided circuits, and making the connections with gold wires further increases the card's cost price.

Connecting the electronic module with the antenna being one of the problems of manufacturing such smart cards, another solution consists in not using a double-sided circuit. This solution described in detail in the patent application FR 2 810 768 consists in transferring and connecting the chip directly onto the antenna before laminating together the various layers that constitute the card. A very thin cavity is then milled in the card body suitable for receiving a single-sided circuit made up of the group of flush contacts. The connections between the chip and the group of contacts are made by a set of connecting pits and routing traces created beforehand on the antenna support and connected to the chip. This solution enables the use of a single-sided circuit and helps relocate the chip in the card body at a place where stresses are the lowest, i.e. at mid-thickness and preferably in a corner. The main problem with such a solution comes from cards intended to be scrapped. The chip is actually inserted right at the start of the card's fabrication process and is discarded with the card if lamination or printing problems occur thereafter, which represents a significant cost in the card's cost price.

### SUMMARY OF THE INVENTION

This is why an object of the invention is to solve the problems of mechanical stresses exerted on the connections between the antenna and the electronic module of a hybrid contact-contactless smart card without increasing the card's cost price.

Another object of the invention is to particularly propose a fabrication process of a hybrid contact-contactless smart card where the connection between the antenna and the electronic module withstands the mechanical bending stresses applied to the card.

The purpose of the invention is thus a double-sided electronic module of a hybrid contact-contactless smart card made on a support that is non-conductive and designed to be lodged in a cavity of the card and to be connected to the bonding pads of the antenna embedded in the card, the cavity including an internal portion for lodging the chip and an external portion whose thickness is lower than that of the internal portion, the module including a group of contacts on one side, some of the contacts each covering a through hole in the support, the group being adapted so that the contacts are flush with the card surface. According to a main characteristic of the invention, on the second side of the module are screen printed first routing traces connected by their first end to the through holes and by the other end to the chip's bonding pads, and second routing traces each connected respectively to a screen printed bonding pad on one side and to two of the chip's bonding pads on the other side, the bonding pads being positioned so that, when inserting the module in the cavity, they are opposite the antenna's bonding pads and allow the module to be bonded along its whole periphery in the external portion provided to this end.

### BRIEF DESCRIPTION OF THE DRAWINGS

The purposes, objects and characteristics of the invention will become more apparent from the following description when taken in conjunction with the accompanying drawings in which:

FIG. 1 represents a section of a double-sided electronic module according to prior art,

FIG. 2 represents the double-sided electronic module according to prior art as seen from the chip side,

FIG. 3 represents a smart card and the location of the cavity capable of receiving the double-sided module according to prior art,

FIG. 4 represents a film on which the single-sided printed circuits are created,

FIG. 5 represents the first side of a double-sided electronic module according to the invention,

FIG. 6 represents the second side of a double-sided electronic module according to the invention,

FIG. 7 represents the second side of a double-sided electronic module according to the invention with the chip,

FIG. 8 represents a smart card and the location of the cavity capable of receiving the double-sided module according to the invention.

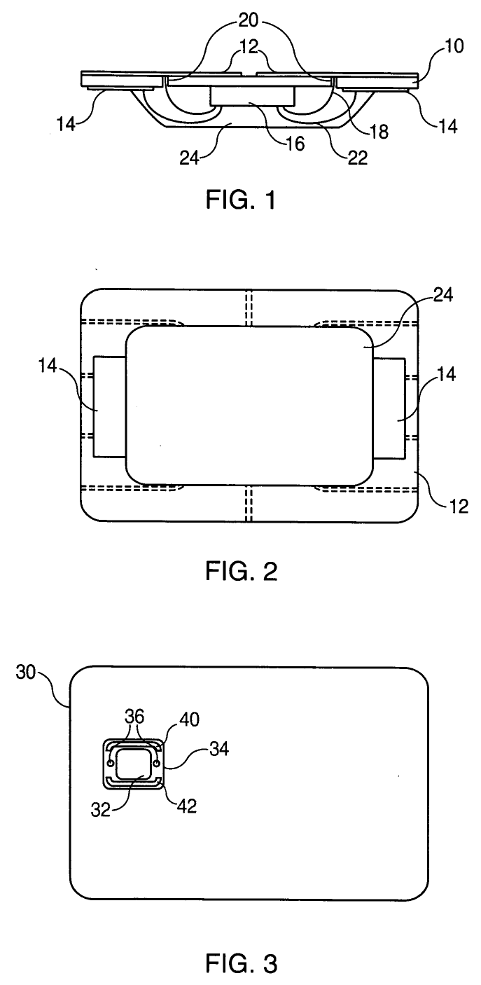

### DETAILED DESCRIPTION OF THE INVENTION

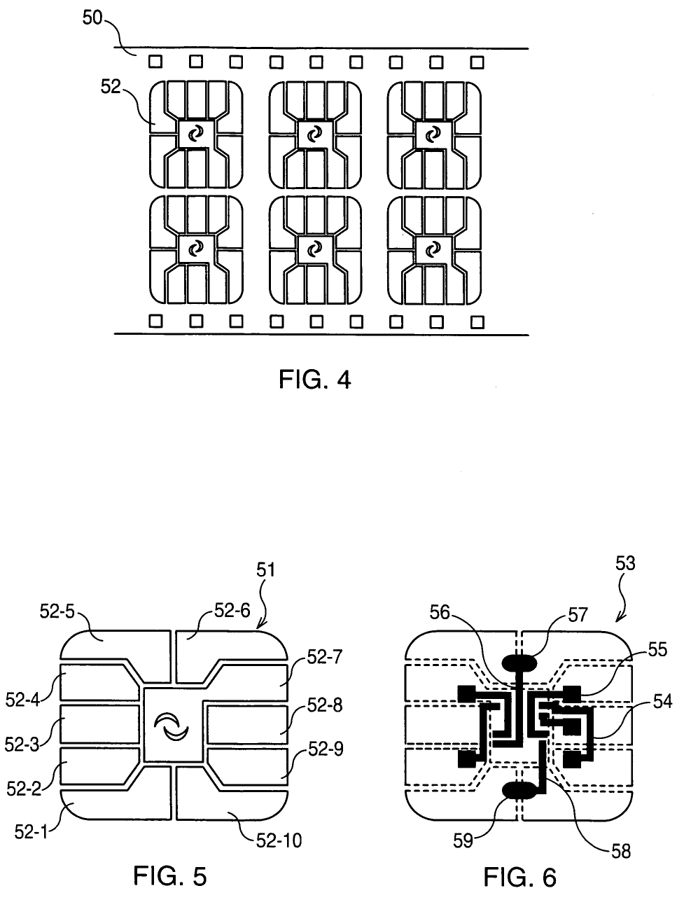

The electronic module which makes the subject of the invention is manufactured from a single-sided circuit as shown in FIG. 4. Each single-sided circuit features the group of flush contacts 52 adapted for being connected to contacts of the reader's reading head. As a de facto standard, the groups are generally made according to a continuous method on the first side of an electrically non-conductive support 50 with a width of 35 mm, 70 mm or 150 mm for 2, 4, and 8 modules. The support 50 is made of epoxy type fibreglass, polyester or paper with a thickness between 0.1 and 0.2 mm. The group of contacts is made of copper but can also be screen-printed with conductive epoxy based ink loaded with silver or gold particles or by screen-printing with a conductive polymer.

With reference to FIG. 5, each electronic module is thus on its first side 51 made up of a group of flush contacts 52-1 to 52-10 of which some are placed over a through hole in the support, not shown in the figure, so as to cover it. There are generally 6 flush contacts that each covers a through hole: 52-2, 52-3, 52-4, 52-7, 52-8, and 52-9. The second side 53 of the module represented in FIG. 6 features a pattern made by screen-printing with conductive ink or continuously screen printed with a conductive polymer on the second side of the film 50. The conductive ink is an epoxy type ink loaded with silver or gold particles. The design represented in black in FIG. 6 is made up of five first routing traces 54 connecting each of the 5 contacts 52 to a location designed to receive a chip's bonding pad and two second routing traces 56 and 58 designed to connect two of the chip's bonding pads to the bonding pads of the card's antenna. The link between the first routing traces 54 and the group of contacts 52-2, 52-3, 52-4, 52-7, and 52-9 is made by means of through holes, the end 55 of each of the traces forming a surface greater than the hole surface so that the latter is covered. The ends 57 and 59 of the second routing traces 56 and 58 form two bonding pads positioned at a distance of about 1.5 mm from the module edges and centred in relation to the two other edges of the module. According to the embodiment described in FIG. 6, the bonding pads 57 et 59 are centred relative to the small sides of the module. Moreover, the pads are aligned in relation to a direction that is parallel to the small sides of the module. When considering the long sides of the module, the pads are sufficiently spaced apart from the edges (preferably by a distance of 1.5 mm or more) in order to free a sufficient area along the whole periphery of the module so that a thin bead of glue can be applied thereon. The bonding pads 57 and 59 and the pads forming the ends 55 of the routing traces 54 are tightly arranged and centred thanks to the use of screen printing and assembling the chip on the module by connecting its active side directly on the antenna's bonding pads according to an assembly process known as “flip-chip”.

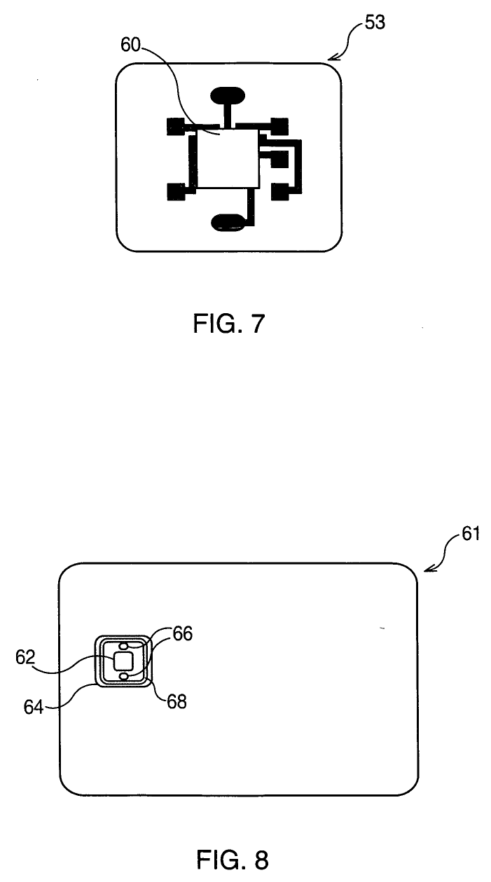

In reference to FIG. 7, the chip of the integrated circuit 60 on which bonding pads, preferably gold bonding pads, are welded, is then placed by gluing using non-conductive glue on the second side 53 of the electronic module in such a way that the chip's bonding pads are placed opposite the ends of the first five routing traces 54. Pressure is then applied to the chip so that the chip's contacts penetrate into the location provided for the routing traces 54, 56, and 58. The double-sided module thus constituted is then detached from its support and glued to the card and connected to the antenna's bonding pads embedded in the card.

The smart card body 61 in standard format 85.6 mm×54 mm shown in FIG. 8 includes several layers laminated together around a support on which is screen printed an antenna whose two ends form the two bonding pads. The antenna preferably consists of an epoxy type conductive ink loaded with silver or a conductive polymer. A cavity is milled in the card body. It includes an internal portion 62 with a thickness of 400 μm which receives the chip 60 and an external portion 64 with a thickness of 180 μm which receives the part of the circuit featuring the group of flush contacts. Two pits 66 are also milled in the external cavity and allow the bonding pads to be moved apart from the antenna. The following step consists in inserting the module by using a glue enabling it to be fixed on the external cavity and a conductive glue enabling the module to be connected to the antenna's bonding pads moved apart thanks to the two pits 66. Conductive glue is first cast at the bottom of the two pits 66 up to the card's antenna contacts. Cyanoacrylate type glue is then placed on the perimeter of the external cavity 64 so that it forms a continuous strip of glue that passes between the cavities 66 and the edge of the external cavity 64.

The internal cavity 62 designed to house the chip is small in relation to a cavity made to house an encased electronic module as shown in FIG. 3. In this manner, the cavities made to move apart the antenna pads are further centred and are advantageously aligned in relation to a transverse direction of the card, that is to say a direction which is parallel to the small sides of the card. The glue is applied on the greyed area 98 in order to form a thin and continuous bead. The large area of the external cavity and the arrangement of the bonding pads allow the bonding to be made along the whole periphery of the module. In this manner, the gluing surface 68 of the module according to the invention is increased by 50% in relation to the gluing surface 40 and 42 of a module according to prior art. The reliability of the connection between the module and the antenna is therefore markedly improved.

The electronic module made in this manner has the advantage of being thin which presents a number of advantages in relation to a traditional module where the chip is encased. The maximum thickness of the cavity milled in the card body is in the order of 400 μm instead of 600 μm in the case of an encased electronic module.

Advantageously, the electrical connection between the antenna's bonding pads and the module is made thanks to silver particles contained in the conductive material cast into the card's connecting pits 66 and in the screen printed ink to create routing traces 55 and 56 and the bonding pads 57 and 58 on the second side of the module and the antenna pads.

Due to the advantages provided by the electronic module according to the invention and its means for connecting to the antenna, the mechanical stresses exerted on the connections between the antenna and the chip are reduced.

However, it is possible to make these connections even more resistant to mechanical stresses by using a conductive glue consisting of a product that has a flexible and semi-rigid consistency, such as silicone or polyurethane, in order to create the electrical junction in the card's cavities 66. As for epoxy type ink, silicone or polyurethane is loaded with silver or carbon to make it conductive. Silver particles represent between 40% and 65% in weight of the final product and have a dimension of 30 to 230 μm, considering that 80% of particles have a size which is 55 μm or less. The silicone or polyurethane-based conductive glue is placed in the card's connecting pits 66 in order to form an electrical junction between the antenna and the module, and it polymerises at ambient temperature without interacting with the cyanoacrylate type glue used to attach the module as silicone and polyurethane do not present any incompatibility with cyanoacrylate type glue. Furthermore, since silicone and polyurethane remain somewhat soft once polymerised, the electrical junction is more resistant to mechanical shear stresses. Break test type mechanical tests performed on cards equipped with this type of electrical connection between the module and the antenna have shown that the card is capable of withstanding 25% more break tests than cards equipped with epoxy type electrical junctions loaded with silver.

1-9. (canceled)

10. A double-sided electronic module of a hybrid contact-contactless smart card made on a non-conductive support and designed to be lodged in a cavity of the card and to be connected to the bonding pads of the antenna which is embedded in the card, said cavity including an internal portion for lodging the chip and an external portion whose thickness is lower than that of said internal portion, said module including a group of contacts on one side of the support, some of the contacts each covering a through hole in the support, said group of contacts being adapted to form the contacts which are flush with the card surface,
wherein, on its second side are screen printed first routing traces connected by their first end to the through holes and by the other end to the chip's bonding pads, and second routing traces, each connected respectively to a screen printed bonding pad on one side and to two of the chip's bonding pads on the other side, said bonding pads being positioned so that, when inserting the module in the cavity, they are opposite the antenna's bonding pads and allow the module to be bonded along its whole periphery in the external portion provided to this end.

11. The electronic module according to claim 10, in which said bonding pads are connected to said antenna's bonding pads through a conductive material forming an electrical junction.

12. The electronic module according to claim 10, in which the antenna and the bonding pads are made by screen printing with conductive ink loaded with silver particles.

13. The electronic module according to claim 12, in which the screen-printing of the first routing traces and bonding pads is done by using conductive ink loaded with silver particles.

14. The electronic module according to claim 11, in which the electric junctions connecting the antenna's bonding pads to the module are made using epoxy type glue loaded with silver particles.

15. The electronic module according to claim 11, in which the electric junctions connecting the antenna's bonding pads to the module are made using silicone loaded with silver particles.

16. The electronic module according to claim 11, in which the electric junctions connecting the antenna's bonding pads to the module are made using polyurethane loaded with silver particles.

17. An electronic module according to claim 10, in which the connecting pads are positioned at a distance greater than 1.5 mm from the edge of the module.

18. A hybrid contact-contactless smart card provided with an electronic module according to claim 10.
